(19) United States
(12) Patent Application Publication
(10) Pub. No.: US 2024/0048136 A1
(43) Pub. Date: Feb. 8, 2024

(54) SEMICONDCUTOR DEVICE

(71) Applicants: National University Corporation Tokai National Higher Education and Research System, Nagoya-shi (JP); TOYODA GOSEI CO., LTD., Kiyosu-shi (JP)

(72) Inventors: Toshihiro IWAKI, Nagoya-shi (JP); Daisuke Arai, Nagoya-shi (JP); Masayoshi Yamamoto, Nagoya-shi (JP); Toshiya Uemura, Kiyosu-shi (JP); Hisao Sato, Kiyosu-shi (JP); Masao Kamiya, Kiyosu-shi (JP)

(21) Appl. No.: 18/207,986

(22) Filed: Jun. 9, 2023

(30) Foreign Application Priority Data
Aug. 5, 2022 (JP) 2022-125290

(51) Int. Cl. H03K 17/081; H03K 17/16; H03K 19/0185

(52) U.S. Cl. CPC H03K 17/08104; H03K 17/162; H03K 19/018521

(57) ABSTRACT

A semiconductor device includes a first transistor including a normally-on transistor with a first source, a first drain, and a first gate and a second transistor including a normally-off transistor with a second source, a second drain electrically connected to the first source, and a second gate. A first gate signal, which turns on later than a second gate signal at the time of turn-on of the device and turns off earlier than the second gate signal at the time of turn-off of the device, is input to the first gate. The second gate signal, which turns on earlier than the first gate signal at the time of the turn-on and turns off later than the first gate signal at the time of the turn-off, is input to the second gate. An amount of delay of each of the first gate signal and the second gate signal is set independently.

### CROSS-REFERENCE TO RELATED APPLICATIONS

The present patent application claims the priority of Japanese patent application No. 2022/125290 filed on Aug. 5, 2022, and the entire contents of Japanese patent application No. 2022/125290 are hereby incorporated by reference.

### TECHNICAL FIELD

The present invention relates to a semiconductor device.

### BACKGROUND ART

A semiconductor device is known in which a switch is constructed by cascode-connecting a normally-on transistor and a normally-off transistor (see, e.g., Patent Literature 1). This semiconductor device includes a normally-off transistor having a first source, a first drain and a first gate, a normally-on transistor having a second source, a second drain electrically connected to the first source, and a second gate, a capacitor having a first end and a second end and electrically connected at the second end to the second gate, a first diode having a first anode electrically connected between the second end and the second gate and a first cathode electrically connected to the second source, a first resistor provided between the first end and the first gate, and a second diode that has a second anode electrically connected to the first end and a second cathode electrically connected to the first gate and is provided in parallel with the first resistor.

In the semiconductor device, when the semiconductor device transitions from the off state to the on state, current flows through the second diode provided in parallel with the first resistor. Therefore, charging of the first gate of the normally-off transistor is not affected by the first resistor. Accordingly, the first gate can be quickly charged. As a result, when the semiconductor device transitions from the off state to the on state, the normally-off transistor can be turned on earlier than the normally-on transistor. In addition, by providing the first resistor, off-timing of the normally-off transistor and off-timing of the normally-on transistor can be delayed by a desired time. Accordingly, when the semiconductor device transitions from the on state to the off state, the normally-on transistor is turned off earlier than the normally-off transistor. This suppresses occurrence of high voltage or overvoltage at a connecting portion between the normally-off transistor and the normally-on transistor.

### CITATION LIST

### Patent Literature

Patent Literature 1: WO 2017/010554

### SUMMARY OF INVENTION

The semiconductor device disclosed in Patent Literature 1 is configured such that a trigger point is delayed by the time constant defined by input capacitance C and resistance R of the transistor. However, since the CR time constant is used to generate the delay, there is a problem that it is difficult to adjust the time constant to achieve both the turn-on sequence and the turn-off sequence. In addition, since the capacitor is used, this acts as a speed-up capacitor and causes the normally-on transistor to switch quickly between turn-on and turn-off, which causes a problem that the conditions for the sequence of turn-on and turn-off cannot be satisfied at the time of turn-on in some cases. Furthermore, when the amount of charge to the gate of the normally-on transistor is large, the charge flows out to the midpoint of the cascode connection through the diode. This causes a problem that charging of the gate of the normally-on transistor does not proceed and it is not possible to turn it on. Therefore, there is a problem that stable turn-on, turn-off operation is not ensured and overvoltage at the midpoint potential of the cascode connection between the normally-on transistor and the normally-off transistor cannot be sufficiently reduced in some cases, hence, it is difficult to improve durable quality of the product.

Therefore, it is an object of the invention to provide a semiconductor device whose durable quality can be improved in a configuration in which a normally-on transistor and a normally-off transistor are cascode-connected.

An aspect of the invention provides a semiconductor device defined by (1) to (5) below.
(1) A semiconductor device, comprising:
   a first transistor comprising a normally-on transistor with a first source, a first drain, and a first gate; and
   a second transistor comprising a normally-off transistor with a second source, a second drain electrically connected to the first source, and a second gate,
   wherein a first gate signal, which turns on later than a second gate signal at the time of turn-on of the device and turns off earlier than the second gate signal at the time of turn-off of the device, is input to the first gate,
   wherein the second gate signal, which turns on earlier than the first gate signal at the time of the turn-on and turns off later than the first gate signal at the time of the turn-off, is input to the second gate, and
   wherein an amount of delay of each of the first gate signal and the second gate signal is set independently.
(2) The semiconductor device defined by (1), further comprising:
   a first gate control unit which is configured such that a first diode connected in series with a first delay unit and exhibiting forward characteristics from an input side to an output side is connected in parallel with a second diode exhibiting reverse characteristics from the input side to the output side and the output side of the first gate control unit is connected to the first gate; and
   a second gate control unit which is configured such that a third diode connected in series with a second delay unit and exhibiting reverse characteristics from the input side to the output side is connected in parallel with a fourth diode exhibiting forward characteristics from the input side to the output side and the output side of the second gate control unit is connected to the second gate,
   wherein a drive signal is input to the input side of the first and second gate control units, and the first and second gate signals are generated from the same drive signal.
(3) The semiconductor device defined by (2), wherein the drive signal is input to the input side of the first gate control unit through a level shifter circuit.
(4) The semiconductor device defined by any one of (1) to (3), wherein the first transistor comprises a normally-on power device that satisfies Qg/Id (a gate charge Qg divided by an absolute maximum rating for a drain current Id (continuous) at Tc=25° C.)≥0.5 nC/A.
(5) The semiconductor device defined by (4), wherein the first transistor further comprises a PSJ GaNFET.

### ADVANTAGEOUS EFFECTS OF INVENTION

According to an aspect of the invention, it is possible to provide a semiconductor device whose durable quality can be improved in a configuration in which a normally-on transistor and a normally-off transistor are cascode-connected.

### BRIEF DESCRIPTION OF DRAWINGS

FIG. 1A is a circuit diagram illustrating a circuit configuration of a semiconductor device in the first embodiment of the present invention.

FIG. 1B is a signal waveform diagram showing a timing relationship between a first gate signal and a second gate signal.

FIG. 2 is a circuit diagram illustrating a circuit configuration of a semiconductor device in the second embodiment of the invention.

FIG. 3 is a circuit diagram illustrating a circuit configuration of a semiconductor device in the third embodiment of the invention.

FIG. 4A is a circuit configuration diagram in Example.

FIG. 4B is a signal waveform diagram illustrating each signal actually measured at the time of turn-on.

FIG. 4C is a signal waveform diagram illustrating each signal actually measured at the time of turn-off.

FIG. 5A is a waveform diagram illustrating each signal actually measured at the time of turn-off in Comparative Example.

FIG. 5B is a waveform diagram illustrating each signal actually measured at the time of turn-off in the present embodiment.

### DESCRIPTION OF EMBODIMENTS

### First Embodiment of the Invention

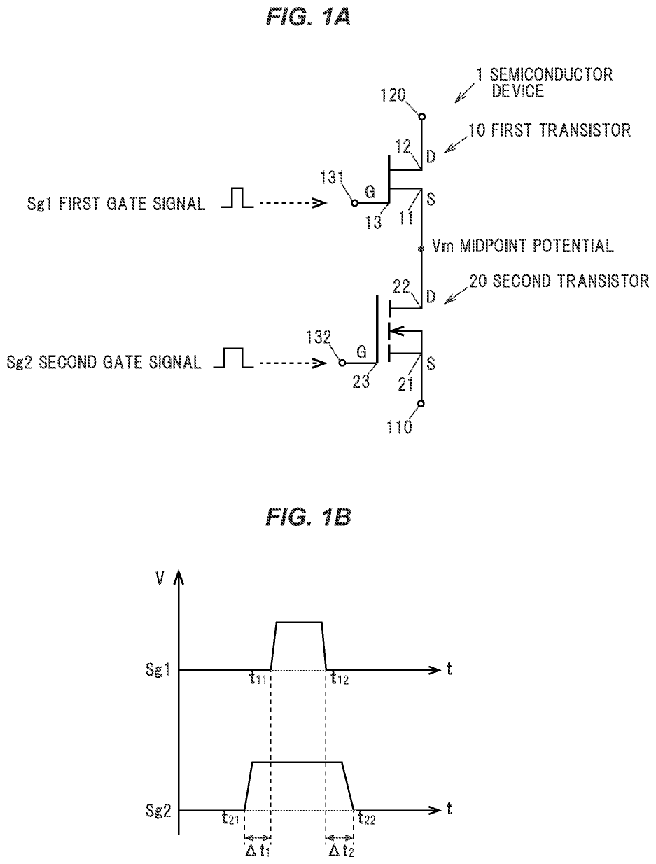

FIG. 1A is a circuit diagram illustrating a circuit configuration of a semiconductor device in the first embodiment of the invention. A semiconductor device 1 in the embodiment of the invention is configured such that a normally-on transistor and a normally-off transistor are cascode-connected, and there is provided a means capable of setting any amount of delay for gate signals which are input to the first and second gates and are to be trigger signals at the time of turn-on and at the time of turn-off of the device, so that overvoltage at the midpoint potential can be sufficiently reduced to improve durable quality of the product. The semiconductor device 1 in the embodiment of the invention is applicable to, e.g., a high breakdown voltage power module that can be used at, e.g., 1.2 kV, 3 kV, 10 kV.

The semiconductor device 1 in the first embodiment has a first transistor 10, which is a normally-on transistor and has a first source 11, a first drain 12 and a first gate 13, and a second transistor 20, which is a normally-off transistor and has a second source 21, a second drain 22 electrically connected to the first source 11 and a second gate 23. A first gate signal Sg1, which turns on later than a second gate signal Sg2 at the time of turn-on and turns off earlier than the second gate signal Sg2 at the time of turn-off, is input to the first gate 13, the second gate signal Sg2, which turns on earlier than the first gate signal Sg1 at the time of the turn-on and turns off later than the first gate signal Sg1 at the time of the turn-off, is input to the second gate Sg2, and an amount of delay of each of the first gate signal and the second gate signal is set independently.

Regarding the first gate signal Sg1 and the second gate signal Sg2, the amount of delay of each of the first gate signal and the second gate signal is set independently. As an example, each gate signal can be output at any timing by a gate driver IC, etc., with a built-in pulse generator.

The first transistor 10 is a normally-on transistor that conducts current even when gate voltage is not applied to the gate. The normally-on transistor has a high element breakdown voltage. As an example, the normally-on transistor is a PSJ GaNFET (Polarization Super Junction GaN Field Effect Transistor), and has a breakdown voltage of 1.2 kV, 3 kV, 10 kV, etc.

The second transistor 20 is a normally-off transistor that does not conduct current unless gate voltage is applied to the gate. The normally-off transistor has a low element breakdown voltage. As an example, the normally-off transistor is a MOSFET (Metal Oxide Semiconductor Field Effect Transistor) using a Si semiconductor.

The first transistor 10 is configured to have the first source 11, the first drain 12, and the first gate 13. The second transistor 20 is configured to have the second source 21, the second drain 22, and the second gate 23.

As shown in FIG. 1A, the first source 11 is connected to the second drain 22. The first drain 12 is connected to a drain terminal 120. The first gate 13 is connected to a gate terminal 131. The connection here means electrical ohmic connection, and the same applies hereinafter.

The second source 21 is connected to a source terminal 110. The second drain 22 is connected to the first source 11. The second gate 23 is connected to a gate terminal 132. FIG. 1B is a signal waveform diagram showing a timing relationship between the first gate signal and the second gate signal. The amount of delay of each of the first gate signal and the second gate signal can be set independently. Voltage V of the first gate signal Sg1 rises from zero to a predetermined voltage at time t11 and falls to zero at time t12. Voltage V of the second gate signal Sg2 rises from zero to a predetermined voltage at time t21, and falls to zero at time t22. The respective predetermined voltages are voltages which are not less than the threshold values to respectively turn on the first transistor 10 and the second transistor 20.

Here, the rise time t11 of the first gate signal Sg1 is delayed by Δt1 from the rise time t21 of the second gate signal Sg2. The fall time t22 of the second gate signal Sg2 is delayed by Δt2 from the fall time t12 of the first gate signal Sg1.

The first gate signal Sg1 is input to the gate terminal 131 and applied to the first gate 13 of the first transistor 10. Meanwhile, the second gate signal Sg2 is input to the gate terminal 132 and applied to the second gate 23 of the second transistor 20.

Thus, the first transistor 10 is turned on later than the second transistor 20 at the time of turn-on and is turned off earlier than the second transistor 20 at the time of turn-off. Meanwhile, the second transistor 20 is turned on earlier than the first transistor 10 at the time of turn-on and is turned off later than the first transistor 10 at the time of turn-off.

### Operation of the Semiconductor Device 1

The semiconductor device 1 is configured such that the normally-on transistor and the normally-off transistor are cascode-connected and the gates are driven separately by providing a means capable of setting any amount of delay for gate signals which are input to the first and second gates and are to be trigger signals at the time of turn-on and at the time of turn-off of the device. That is, the two FETs, the normally-on transistor and the normally-off transistor, are configured to perform a switching operation, etc., as a composite FET which acts as a normally-off transistor.

When the semiconductor device 1 is turned on, the second gate signal Sg2 shown in FIG. 1B is input to the gate terminal 132 and applied to the second gate 23 of the second transistor 20. Meanwhile, the first gate signal Sg1 is input to the gate terminal 131 and applied to the first gate 13 of the first transistor 10, with a delay of a predetermined delay amount Δt1. Thus, the second transistor 20 is turned on first and the first transistor 10 is then turned on with a delay, and the semiconductor device 1 thereby turns to the on state.

At the time of the above-described turn-on of the semiconductor device 1, the second transistor 20 is turned on first, hence, a midpoint potential Vm at a connecting point between the first source 11 and the second drain 22 is grounded. Thus, during the transition, the charge at the midpoint potential Vm decreases quickly and this allows overvoltage at the midpoint potential Vm to be sufficiently reduced.

When the semiconductor device 1 is turned off, the first gate signal Sg1 shown in FIG. 1B is input to the gate terminal 131 and applied to the first gate 13 of the first transistor 10. Meanwhile, the second gate signal Sg2 is input to the gate terminal 132 and applied to the second gate 23 of the second transistor 20, with a delay of a predetermined delay amount Δt2. Thus, the first transistor 10 is turned off first and the second transistor 20 is then turned off with a delay, and the semiconductor device 1 thereby turns to the off state.

At the time of the above-described turn-off of the semiconductor device 1, the first transistor 10 is turned off first but the second transistor 20 is still on, hence, the midpoint potential Vm at the connecting point between the first source 11 and the second drain 22 is in a grounded state. Thus, during the transition, the charge at the midpoint potential Vm decreases quickly and this allows overvoltage at the midpoint potential Vm to be sufficiently reduced.

### Second Embodiment of the Invention

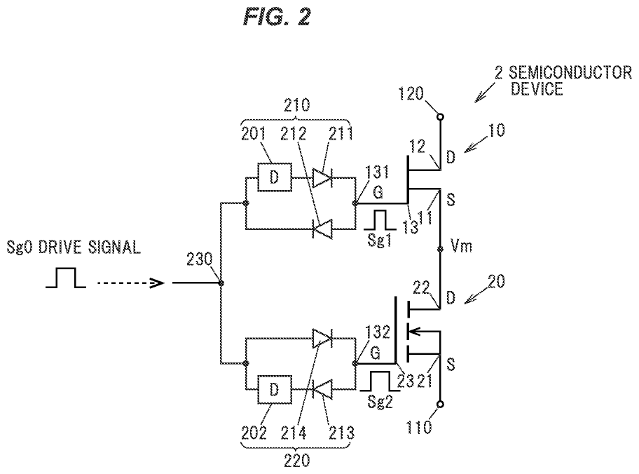

FIG. 2 is a circuit diagram illustrating a circuit configuration of a semiconductor device in the second embodiment of the invention. A semiconductor device 2 in the second embodiment is configured such that the first gate signal Sg1 and the second gate signal Sg2 are respectively input to the first gate 13 and the second gate 23 through gate control units including delay units. Thereby, the first gate signal Sg1 and the second gate signal Sg2 are generated from the same drive signal Sg0, so that drive control of the semiconductor device 2 can be performed by one drive signal Sg0.

In the semiconductor device 2 of the second embodiment, a first gate control unit 210 is configured such that a first diode 211 connected in series with a first delay unit 201 and exhibiting forward characteristics from an input side to an output side is connected in parallel with a second diode 212 exhibiting reverse characteristics from the input side to the output side and the output side of the first gate control unit 210 is connected to the first gate 13. In addition, a second gate control unit 220 is configured such that a third diode 213 connected in series with a second delay unit 202 and exhibiting reverse characteristics from the input side to the output side is connected in parallel with a fourth diode 214 exhibiting forward characteristics from the input side to the output side and the output side of the second gate control unit 220 is connected to the second gate 23. The amount of delay of each of the first delay unit 201 and the second delay unit 202 can be set independently in the same manner as the first embodiment. The drive signal Sg0 is input to an input-side terminal 230 of the first gate control unit 210 and the second gate control unit 220, and the first gate signal Sg1 and the second gate signal Sg2 each with an independently set delay are generated from the same drive signal Sg0.

A diode which provides rectifying action can be used as each of the first diode 211, the second diode 212, the third diode 213 and the fourth diode 214. Meanwhile, various types of delay devices can be used as the first delay unit 201 and the second delay unit 202 and it is possible to use delay ICs, etc., each capable of independently setting the amount of delay. The remaining configuration is the same as in the first embodiment.

### Operation of the Semiconductor Device 2

The semiconductor device 2 is configured such that the normally-on transistor and the normally-off transistor are cascode-connected and are operated respectively by the first gate signal Sg1 and the second gate signal Sg2 that are generated from the same drive signal Sg0 through delay lines. That is, the two FETs, the normally-on transistor and the normally-off transistor, are configured to perform a switching operation, etc., as a composite FET which acts as a normally-off transistor.

When the semiconductor device 2 is turned on, the drive signal Sg0 input to the input-side terminal 230 is input to the first gate 13 through the first delay unit 201 and the first diode 211 of the first gate control unit 210. Meanwhile, the second diode 212 of the first gate control unit 210 does not operate due to reverse characteristics. Therefore, the first gate signal Sg1 is input to the first gate 13 in such a manner the rise of the first gate signal Sg1 is delayed by a predetermined time from the rise of the drive signal Sg0.

The drive signal Sg0 input to the input-side terminal 230 is also input to the second gate 23 through the fourth diode 214. Meanwhile, the third diode 213 of the second gate control unit 220 does not operate due to reverse characteristics. Therefore, the second gate signal Sg2 is input to the second gate 23 as a signal without delay in such a manner the rise of the second gate signal Sg2 is at the same timing as the rise of the drive signal Sg0.

Thus, the second transistor 20 is turned on first and the first transistor 10 is then turned on with a delay, and the semiconductor device 2 thereby turns to the on state. At the time of turn-on of the semiconductor device 2, the second transistor 20 is turned on first, hence, the midpoint potential Vm at the connecting point between the first source 11 and the second drain 22 is grounded. Thus, during the transition, the charge at the midpoint potential Vm decreases quickly and this allows overvoltage at the midpoint potential Vm to be sufficiently reduced.

When the semiconductor device 2 is turned off, the gate terminal 131 on the transistor 10 side has a higher potential than the input-side terminal 230 of the gate control unit 210. Thus, the first diode 211 of the first gate control means 210 does not operate due to reverse characteristics. Thus, equivalently, the first gate signal Sg1 is input to the first gate 13 as a signal without delay in such a manner the fall of the first gate signal Sg1 is at the same timing as the fall of the drive signal Sg0.

Meanwhile, the fourth diode 214 of the second gate control unit 220 does not operate due to reverse characteristics. Thus, equivalently, the second gate signal Sg2 is input to the second gate 23 as a delayed signal in such a manner the fall of the second gate signal Sg2 is delayed by a predetermined time from the fall of the drive signal Sg0.

At the time of the above-described turn-off of the semiconductor device 2, the first transistor 10 is turned off first but the second transistor 20 is still on, hence, the midpoint potential Vm at the connecting point between the first source 11 and the second drain 22 is in a grounded state. Thus, during the transition, the charge at the midpoint potential Vm decreases quickly and this allows overvoltage at the midpoint potential Vm to be sufficiently reduced.

As described above, equivalently, trigger signals of the first gate signal Sg1 and the second gate signal Sg2 in the second embodiment are generated from the same drive signal Sg0. The first transistor 10 and the second transistor 20 can be thereby driven.

### Third Embodiment of the Invention

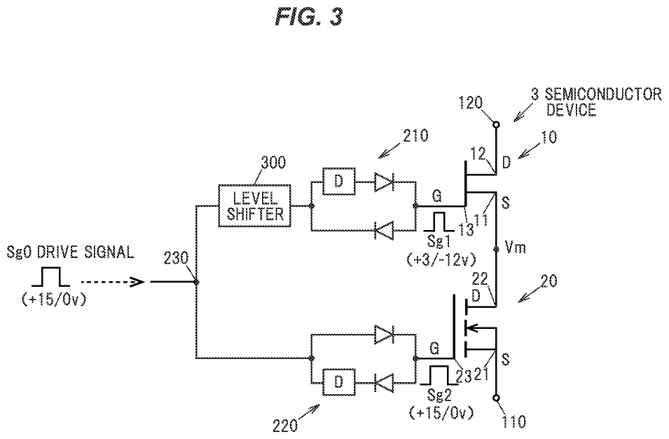

FIG. 3 is a circuit diagram illustrating a circuit configuration of a semiconductor device in the third embodiment of the invention. A semiconductor device 3 in the third embodiment is configured such that the drive signal input to the input side of the first gate control unit is input through a level shifter circuit. It is thereby possible to apply different gate voltages to the first transistor 10 and the second transistor 20.

As shown in FIG. 3, in the semiconductor device 3, the drive signal Sg0 is input to the input side of the first gate control unit 210 through a level shifter circuit 300. As an example, a DC-to-DC converter circuit can be used as the level shifter circuit 300. The remaining configuration is the same as in the second embodiment.

As an example, when the drive signal Sg0 operates in a voltage range of +15V to 0V and assuming that an amount of level shift produced by the level shifter circuit 300 is −12V, the first gate signal Sg1 is from +3V to −12 V and the second gate signal Sg2 is from +15V to 0V.

### Turn-On Waveform and Turn-Off Waveform in Example

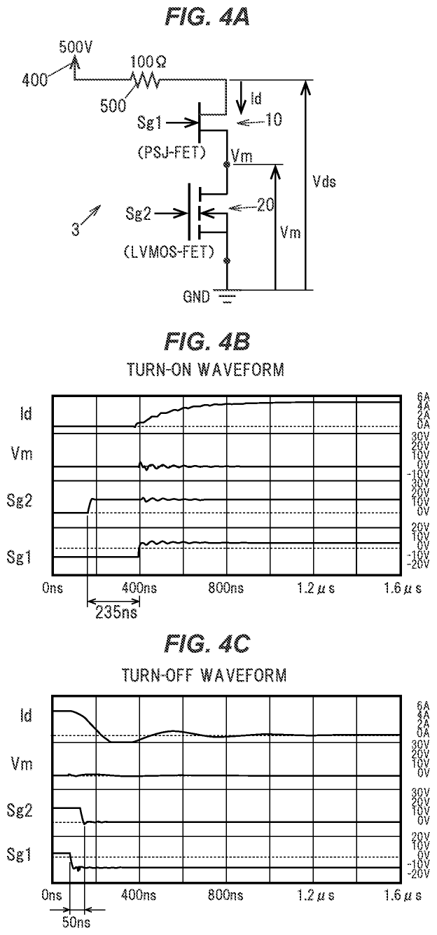

FIG. 4A is a circuit configuration diagram in Example, FIG. 4B is a signal waveform diagram illustrating each signal actually measured at the time of turn-on, and FIG. 4C is a signal waveform diagram illustrating each signal actually measured at the time of turn-off

As shown in FIG. 4A, the semiconductor device 3 is connected to a 500V supply voltage 400 through a 100ω load resistor 500 to operate it as a low-side switch.

As shown in FIG. 4B, at the time of turn-on, the first gate signal Sg1 is a signal delayed from the second gate signal Sg2, and the delay time is 235 ns. The second gate signal Sg2 is input to the second gate 23, and after the 235 ns mentioned above, the first gate signal Sg1 is input to the first gate 13 and the first transistor 10 is thereby turned on. A drain current Id thereby increases and the semiconductor device 3 turns to the on state. At this turn-on time, the midpoint potential Vm at the connecting point between the first source 11 and the second drain 22 hardly fluctuates, and overvoltage during the transition is sufficiently suppressed.

As shown in FIG. 4C, at the time of turn-off, the second gate signal Sg2 is a signal delayed from the first gate signal Sg1, and the delay time is 50 ns. The first gate signal Sg1 is input to the first gate 13, and after the 50 ns mentioned above, the second gate signal Sg2 is input to the second gate 23 and the second transistor 20 is thereby turned off. The drain current Id thereby decreases and the semiconductor device 3 turns to the off state. At this turn-off time, the midpoint potential Vm at the connecting point between the first source 11 and the second drain 22 hardly fluctuates, and overvoltage during the transition is sufficiently suppressed.

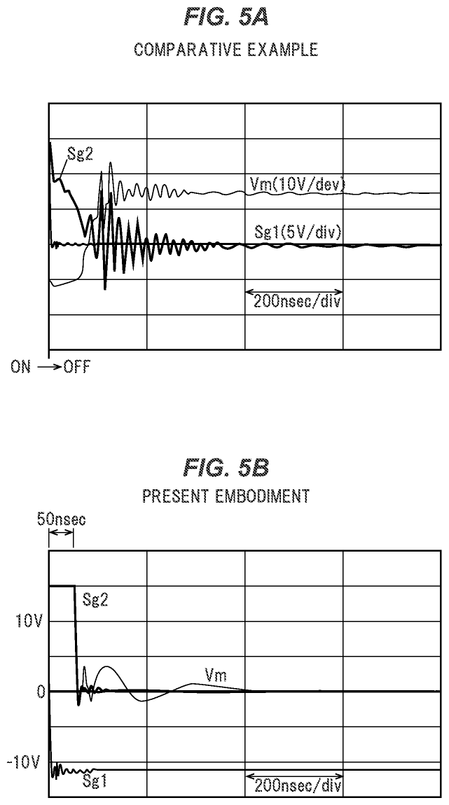

FIG. 5A is a waveform diagram illustrating each signal actually measured at the time of turn-off in Comparative Example, and FIG. 5B is a waveform diagram illustrating each signal actually measured at the time of turn-off in the present embodiment.

The case where the first gate signal Sg1 and the second gate signal Sg2 drive the first transistor 10 and the second transistor 20 at the same timing is shown as Comparative Example. FIG. 5A shows that the midpoint potential Vm at the connecting point between the first source 11 and the second drain 22 jumps up to 25 to 28 V during the transition.

Next, the case where the second gate signal Sg2 is delayed by 50 ns from the first gate signal Sg1 and the first transistor 10 and the second transistor 20 are driven will be described. FIG. 5B shows that even during the transition, the midpoint potential Vm at the connecting point between the first source 11 and the second drain 22 remains within about 5 to 8V which is a steady off state.

### Effects of the Embodiments

The semiconductor devices in the embodiments of the invention have the following effects.
(1) The amount of delay of each of the first gate signal and the second gate signal can be set independently. Unlike the conventional technique, the amount of delay of each signal can be set independently without using the CR time constant, etc., hence, timing of switching operation of the two FETs, a normally-on transistor and a normally-off transistor, at the time of turn-on and at the time of turn-off can be set independently. This allows two FETs, a normally-on transistor and a normally-off transistor, to perform a switching operation, etc., as a composite FET which acts as a normally-off transistor. In addition, since the amount of delay of each of the first gate signal and the second gate signal can be set independently, the midpoint potential Vm can be finely set so as to be optimum, allowing switching operation as a composite FET to be performed more reliably.
(2) During the transition, the charge at the midpoint potential Vm decreases quickly and this allows overvoltage at the midpoint potential Vm to be sufficiently reduced. This makes it possible to provide a semiconductor device whose durable quality can be improved in a configuration in which a normally-on transistor and a normally-off transistor are cascode-connected.
(3) In the embodiments, the normally-on transistor is mainly responsible for switching of the semiconductor device which is thus not affected by the switching speed of the normally-off transistor. This allows an improvement in switching speed since it is affected only by the switching speed of the normally-on transistor.
(4) According to the semiconductor devices in the embodiments, effects such as small circuit size, small heat generation from the circuit and small temperature dependence can be expected.
(5) What is most likely to occur in the event of driver circuit failure is that, e.g., a 15V power supply for gate driver is shorted to about 0V. At this time, the supply voltage to the second gate 23 of the second transistor 20 and the supply voltage to the first gate 13 of the first transistor 10 both drop to about 0V, and the second transistor 20 is fixed in the off state. Then, by the rise of the potential at the first source 11 of the first transistor 10, voltage Vgs between the first gate 13 and the first source 11 becomes negative, the first transistor 10 also enters the off state due to the principle of cascode connection, and the entire device turns to the off state. This provides a fail-safe feature.
(6) The FET in the embodiments can be applied to cascode connection of a normally-on power device which has a breakdown voltage of not less than 600V and satisfies Qg/Id (a gate charge Qg divided by an absolute maximum rating for a drain current Id (continuous) at Tc=25° C.)≥0.5 nC/A. This is because it can be considered that the larger the Qg/Id, the longer it takes to turn the normally-on transistor to the completely off state and thus the greater the effect of the measure against jumps in Vm by the delay. Then, since Qg/Id of PSJ GaNFET is 1.5 nC/A, the first transistor 10, which is a normally-on transistor, is applicable to PSJ GaNFET. The PSJ GaNFET has a high breakdown voltage of 1.2 kV, 3 kV, 10 kV, etc., and thus can function as a high breakdown-voltage normally-off transistor according to the embodiments.

Although the embodiments of the invention have been described, the invention is not limited to the embodiments described above and the various kinds of modifications can be implemented without departing from the gist of the invention. Although the embodiments of the invention have been described using the example in which N-channel FETs are cascode-connected, the embodiments are also applicable to the case where P-channel FETs are cascode-connected.

In addition, the embodiments described above do not limit the invention according to claims. Further, please note that not all combinations of the features described in the embodiments are necessary to solve the problem of the invention.

### REFERENCE SIGNS LIST

1, 2, 3 SEMICONDUCTOR DEVICE
10 FIRST TRANSISTOR
11 FIRST SOURCE
12 FIRST DRAIN
13 FIRST GATE
20 SECOND TRANSISTOR
21 SECOND SOURCE
22 SECOND DRAIN
23 SECOND GATE
110 SOURCE TERMINAL
120 DRAIN TERMINAL
131 GATE TERMINAL
132 GATE TERMINAL
201 FIRST DELAY UNIT
202 SECOND DELAY UNIT
210 FIRST GATE CONTROL UNIT
211 FIRST DIODE
212 SECOND DIODE
213 THIRD DIODE
214 FOURTH DIODE
220 SECOND GATE CONTROL UNIT
230 INPUT-SIDE TERMINAL
300 LEVEL SHIFTER CIRCUIT
400 SUPPLY VOLTAGE
500 LOAD RESISTOR
Sg0 DRIVE SIGNAL
Sg1 FIRST GATE SIGNAL
Sg2 SECOND GATE SIGNAL
Vm MIDPOINT POTENTIAL

1. A semiconductor device, comprising:
a first transistor comprising a normally-on transistor with a first source, a first drain, and a first gate; and
a second transistor comprising a normally-off transistor with a second source, a second drain electrically connected to the first source, and a second gate,
wherein a first gate signal, which turns on later than a second gate signal at the time of turn-on of the device and turns off earlier than the second gate signal at the time of turn-off of the device, is input to the first gate,
wherein the second gate signal, which turns on earlier than the first gate signal at the time of the turn-on and turns off later than the first gate signal at the time of the turn-off, is input to the second gate, and
wherein an amount of delay of each of the first gate signal and the second gate signal is set independently.

2. The semiconductor device according to claim 1, further comprising:
a first gate control unit which is configured such that a first diode connected in series with a first delay unit and exhibiting forward characteristics from an input side to an output side is connected in parallel with a second diode exhibiting reverse characteristics from the input side to the output side and the output side of the first gate control unit is connected to the first gate; and
a second gate control unit which is configured such that a third diode connected in series with a second delay unit and exhibiting reverse characteristics from the input side to the output side is connected in parallel with a fourth diode exhibiting forward characteristics from the input side to the output side and the output side of the second gate control unit is connected to the second gate,
wherein a drive signal is input to the input side of the first and second gate control units, and the first and second gate signals are generated from the same drive signal.

3. The semiconductor device according to claim 2, wherein the drive signal is input to the input side of the first gate control unit through a level shifter circuit.

4. The semiconductor device according to claim 1, wherein the first transistor comprises a normally-on power device that satisfies Qg/Id (a gate charge Qg divided by an absolute maximum rating for a drain current Id (continuous) at Tc=25° C.)≥0.5 nC/A.

5. The semiconductor device according to claim 4, wherein the first transistor further comprises a PSJ GaNFET.
